(19) United States
(12) Patent Application Publication
(10) Pub. No.: US 2005/0282324 A1
(43) Pub. Date: Dec. 22, 2005

(54) Semiconductor device containing distorted silicon layer formed on silicon germanium layer

(75) Inventor: Kazuya Ohuchi, Yokohama-shi (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/148,449

(22) Filed: Jun. 9, 2005

(30) Foreign Application Priority Data
Jun. 10, 2004 (JP) 2004-172744

(51) Int. Cl. H01L 21/336; H01L 21/331; H01L 27/01; H01L 21/8234; H01L 21/8222; H01L 27/12; H01L 31/0392

(52) U.S. Cl. 438/198; 438/320; 257/350

(57) ABSTRACT

A semiconductor device includes a silicon germanium layer, a silicon layer and a silicide layer. The silicon germanium layer is formed on a semicon-ductor substrate. The silicon layer is formed on the silicon germanium layer. The silicide layer is formed in a surface region of the silicon layer. A germanium concentration of the silicon layer that is in contact with the silicide film is 10% or less.

### CROSS-REFERENCE TO RELATED APPLICATIONS

This application is based upon and claims the benefit of priority from prior Japanese Patent Application No. 2004-172744, filed Jun. 10, 2004, the entire contents of which are incorporated herein by reference.

### BACKGROUND OF THE INVENTION

1. Field of the Invention

The present invention relates to a semiconductor device and a method of manufacturing the semiconductor device, and more specifically to a semiconductor device containing, for example, a distorted silicon layer formed on a silicon germanium layer.

2. Description of the Related Art

In recent years, a MOS field effect transistor (to be abbreviated as MOSFET hereinafter) in which a distorted silicon layer is formed on a silicon germanium layer has become a focus of attention. The MOSFET has the following structure. A silicon germanium (SiGe) layer is formed on a silicon semiconductor substrate, and a S distorted silicon layer is formed on the silicon germanium layer. The thus formed substrate is used for this MOSFET. In more detail, the MOSFET is formed on the distorted silicon layer so as to use this distorted silicon layer as a channel. (See, for example, Jpn. Pat. Appln. KOKAI Publication No. 2002-94060.) It is conventionally known that a distorted silicon layer having such a structure has higher transfer degrees of electrons and holes as compared to those of the conventional silicon layer. Therefore, when a MOSFET is formed on a distorted silicon layer, the transistor characteristics can be improved as compared to the case of the conventional MOSFET.

Usually, in a MOSFET, a silicide film is formed on a source region and a drain region. When the silicide layer reaches the silicon germanium layer, an increase in junction leak current or a contact error occurs. This is because there is a poor affinity between a silicide film and silicon germanium (SiGe). More specifically, due to thermal instability of three-element compound, NiSiGe, formed by the reaction between silicide and silicon germanium, the resistance of the portions of the source electrode and drain electrode, on which silicide is formed, is dispersed. Further, the junction leak current is increased and its dispersion is increased. Furthermore, the dispersion of the resistance of the contact portion formed on the three-element compound is increased. As a result, the MOSFET entails drawbacks of deterioration of the transistor characteristics and lowering of the yield of the MOSFET.

### BRIEF SUMMARY OF THE INVENTION

According to an aspect of the present invention, there is provided a semiconductor device comprising a silicon germanium layer, a silicon layer and a silicide layer. The silicon germanium layer is formed on a semiconductor substrate. The silicon layer is formed on the silicon germanium layer. The silicide layer is formed in a surface region of the silicon layer. A germanium concentration of the silicon layer that is in contact with the silicide film is 10% or less.

According to another aspect of the present invention, there is provided a semiconductor device comprising a silicon germanium layer, a silicon layer, a first source region and a first drain region, a gate insulating film, a gate electrode, a second source region and a second drain region, and silicide films. The silicon germanium layer is formed on a semicon-ductor substrate. The silicon layer is formed on the silicon germanium layer. The first source region and the first drain region are formed to be apart from each other in a surface region of the silicon layer. The gate insulating film is formed on the silicon layer and between the first source region and the first drain region. The gate electrode is formed on the gate insulating film. The second source region and the second drain region are formed on the first source region and the first drain region respectively, the second source region and the second drain region being each formed of a silicon film. The silicide films are formed on the second source region and the second drain region.

### BRIEF DESCRIPTION OF THE SEVERAL VIEWS OF THE DRAWING

FIG. 1 is a cross sectional view showing the structure of a semiconductor device containing a MOSFET, according to the first embodiment of the present invention;

FIG. 2 is a diagram showing the relationship between the Ge concentration of the silicon layer in contact with the nickel silicide film and the resistance of the source and drain regions in the first embodiment;

FIG. 3 is a cross sectional view illustrating a first step of the method of manufacturing the semiconductor device according to the first embodiment;

FIG. 4 is a cross sectional view illustrating a second step of the method of manufacturing the semiconductor device according to the first embodiment;

FIG. 5 is a cross sectional view illustrating a third step of the method of manufacturing the semiconductor device according to the first embodiment;

FIG. 6 is a cross sectional view illustrating a fourth step of the method of manufacturing the semiconductor device according to the first embodiment;

FIG. 7 is a cross sectional view illustrating a fifth step of the method of manufacturing the semiconductor device according to the first embodiment;

FIG. 8 is a cross sectional view illustrating a sixth step of the method of manufacturing the semiconductor device according to the first embodiment;

FIG. 9 is a cross sectional view illustrating the silicon layer and nickel layer formed on the silicon germanium layer, and a nickel silicide layer formed from these layers in the first embodiment;

FIG. 10 is a cross sectional view showing the structure of a semiconductor device containing a MOSFET, according to the second embodiment of the present invention;

FIG. 11 is a cross sectional view illustrating a first step of the method of manufacturing the semiconductor device according to the second embodiment;

FIG. 12 is a cross sectional view illustrating a second step of the method of manufacturing the semiconductor device according to the second embodiment;

FIG. 13 is a cross sectional view illustrating a third step of the method of manufacturing the semiconductor device according to the second embodiment;

FIG. 14 is a cross sectional view illustrating a fourth step of the method of manufacturing the semiconductor device according to the second embodiment;

FIG. 15 is a cross sectional view illustrating a fifth step of the method of manufacturing the semiconductor device according to the second embodiment;

FIG. 16 is a cross sectional view illustrating a sixth step of the method of manufacturing the semiconductor device according to the second embodiment; and

FIG. 17 is a cross sectional view illustrating a seventh step of the method of manufacturing the semiconductor device according to the second embodiment.

### DETAILED DESCRIPTION OF THE INVENTION

Embodiments of the present invention will now be described with reference to accompanying drawings. In the following descriptions, common parts through out the drawings are designated by the same reference numerals.

### First Embodiment

First, a semiconductor device according to the first embodiment will now be described.

FIG. 1 is a cross sectional diagram showing the structure of the semiconductor device containing the MOSFET according to the first embodiment. As shown, a silicon germanium layer 12 is formed on a silicon semiconductor substrate 11. As the silicon germanium layer 12, a type that has a germanium concentration of 10 to 30% is used. A distorted silicon layer 13 is formed on the silicon germanium layer 12. Then, trenches each separating a respective element region are formed in the silicon layer and silicon germanium layer 12, and an insulating film is embedded in each trench to form an element isolation insulating film (STI (shallow trench isolation)) 14.

In a surface region of the silicon layer 13 of an element region isolated by the element isolation insulating film 14, a source region 15 and a drain region 16 are formed to be apart from each other, and further extension regions 15A and 16A are formed on inner sides of the source region 15 and drain region 16, respectively. A gate insulating film 17 is formed on that portion of the silicon layer 13 which is located between the source region 15 and drain region 16, and a gate electrode 18 is formed on the gate insulating film 17. Further, a sidewall insulating film 20 is formed on a side surface of the gate electrode 18.

A silicide film 19 such as a nickel silicide (NiSi) film, cobalt silicide (CoSi) film or IrSi (iridium silicide) film is formed on the source region 15, drain region 16 and gate electrode 18. The following description will be made in connection with the case where the nickel silicide film 19 is formed as an example. Here, the nickel silicide film 19 is formed on the surfaces of the source region 15 and drain region 16 even over to the insides thereof, but does not reach the silicon germanium layer 12. The silicon layer 13 is present between the nickel silicide film 19 and silicon germanium layer 12. In a strict sense, there are some cases where germanium (Ge) is contained in the silicon layer 13 present between the nickel silicide film 19 and silicon germanium layer 12. In these cases, the Ge concentration of the silicon layer 13 located in the boundary between the nickel silicide film 19 and silicon layer 13 is controlled to 10% or less.

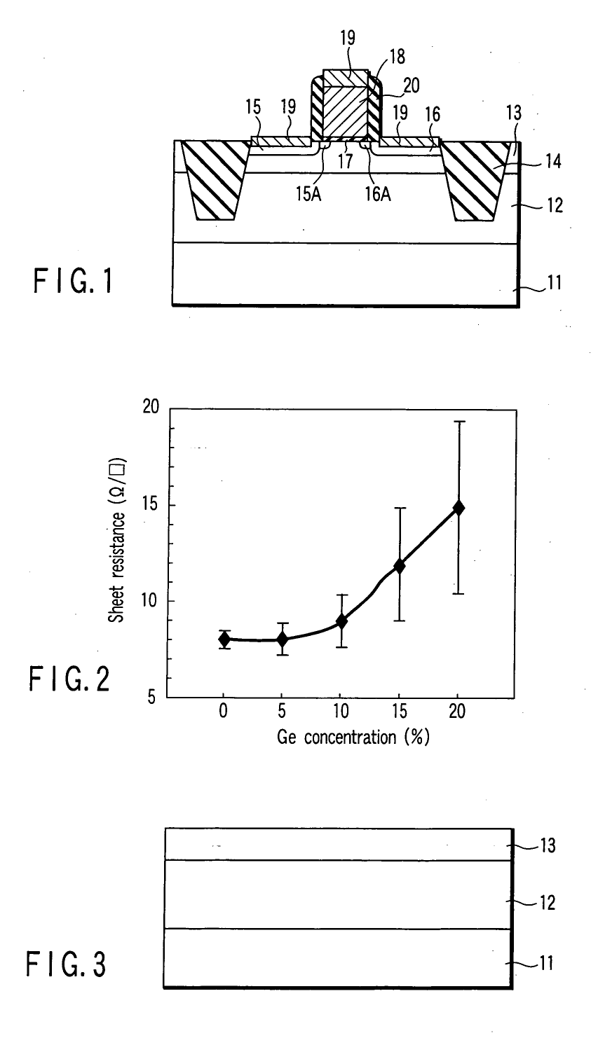

FIG. 2 shows the relationship between the Ge concentration of the silicon layer 13 in contact with the nickel silicide film 19 and the resistance of the source region 15 and drain region 16. As shown in FIG. 2, when the Ge concentration is 10% or less, the sheet resistance is 10Ω/□ or less, whereas the Ge concentration exceeds 10%, the sheet resistance sharply increases. Thus, the sheet resistance sharply increases after the Ge concentration exceeds 10% or further. In other words, when the Ge concentration of the silicon layer 13 brought into contact with the silicide film 19 is controlled to 10% or less, the increase in the resistance value of the source region 15 and drain region 16 can be suppressed. Accordingly, the deterioration of the transistor characteristics in the MOSFET can be prevented.

As described above, according to the first embodiment, a silicon layer or a silicon layer whose Ge concentration is 10% or less is formed between the silicide layer and silicon germanium layer. With this structure, it is possible to prevent the deterioration of the interfacial morphology of the silicide film created by the reaction between silicide and Ge. In this manner, it becomes possible to prevent the dispersion of the resistance of the source region and drain region. Further, it is possible to prevent the increase in the junction leak current as well as the widening of the dispersion. Furthermore, the widening of the dispersion of the contact resistance of the contact portion formed on the source region and drain region, which is the three-element compound, can be presented. As a result, it is possible to suppress the lowering of the yield of the semiconductor device containing the MOSFET.

The method of manufacturing a semiconductor device containing a MOSFET according to the first embodiment shown in FIG. 1 will now be described.

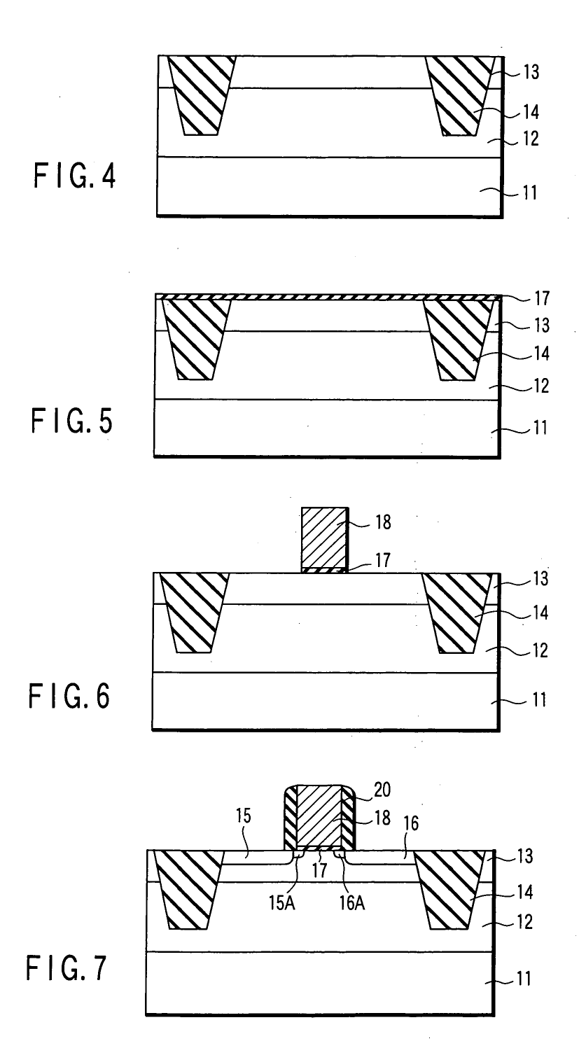

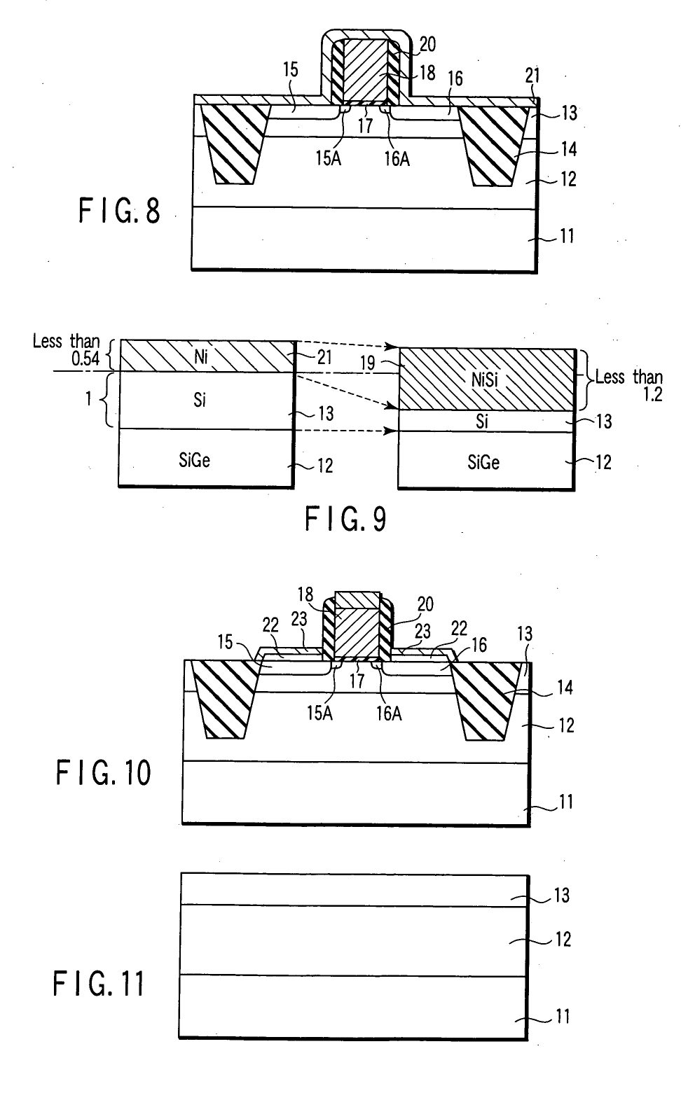

FIGS. 3 to 8 are cross sectional views each showing a respective step in the method of manufacturing the semiconductor device. First, as shown in FIG. 3, the silicon germanium layer 12 is formed on the silicon semiconductor substrate 11 by a CVD method, and further the distorted silicon layer 13 is formed on the silicon germanium layer 12 by a CVD method. Subsequently, as shown in FIG. 4, trenches are formed in the silicon layer 13 and silicon germanium layer 12, and an insulating film is embedded in each trench to form an element isolation insulating film (STI (shallow trench isolation)) 14.

Next, as shown in FIG. 5, a silicon oxide film 17 is formed on the silicon layer 13, and further a polysilicon film 18 is formed on the silicon oxide film 17. Then, the silicon oxide film 17 and polysilicon film 18 are etched by an RIE method, thereby forming a gate insulating film 17 and a gate electrode 18 as shown in FIG. 6.

Subsequently, as shown in FIG. 7, an impurity is introduced to the surface regions of the silicon layer 13 on both sides of the gate electrode 18 by an ion implantation method, thereby forming the extension regions 15A and 16A. After that, a silicon oxide film is formed on the gate electrode 18 and silicon layer 13, and then an anisotropic etching is carried out by an RIE method, thereby forming a sidewall insulating film 20 on a side surface of the gate electrode 18. Further, an impurity is introduced to the surface regions of the silicon layer 13 on both sides of the sidewall insulating film 20 by an ion implantation method, thereby forming the source region 15 and drain region 16.

Next, a high-melting point metal film 21 such as of nickel (Ni), cobalt (Co), erbium (Er), platinum (Pt) or iridium (Ir) is deposited on the structure shown in FIG. 7, including the source region 15, drain region 16, gate electrode 18 and sidewall insulating film 20. In this embodiment, the descriptions will be made in connection with the case where a nickel film 21 is deposited as an example. Subsequently, a heat treatment is carried out to make the silicon layer that constitutes the source region 15 and drain region 16 and the polysilicon film that constitutes the gate electrode 18 react with the nickel film 21. Thus, the nickel film 21 is transformed into a silicide. After that, the unreacted portion of the nickel film 21 is removed, and a nickel silicide film 19 is formed on the source region 15, drain region 16 and gate electrode 18 as shown in FIG. 1.

It should be noted here that the thickness of the nickel film 21 deposited on the silicon layer 13 is set to less than 54% of that of the silicon layer 13 in order to avoid the nickel silicide film 19 formed by the reaction between silicon and nickel from contacting with the silicon germanium layer 12 located underneath the silicon layer 13. FIG. 19 is a cross sectional view of the silicon layer 13 formed on the silicon germanium (SiGe) layer 12 and the nickel layer 21 formed on the silicon layer, and the nickel silicide film 19 formed by the reaction between the silicon layer 13 and the nickel film 21. As shown in this figure, when the thickness of the silicon layer 13 is set to 1 and the thickness of the nickel film 21 is set to less than 0.54 in ratio, the thickness of the thus formed nickel silicide film 19 is less than 1.2, and the silicon layer 13 remains between the silicon germanium layer 12 and the nickel silicide film 19. This is because when the thickness of the silicon layer is set to 1 and the thickness of the nickel film is set to 0.54 in ratio, the silicon layer and the nickel film react entirely with each other to form a nickel silicide film having a thickness of 1.2. In other words, when the thickness of the nickel film is set to less than 0.54 in terms of ratio, an unreacted portion of the silicon layer can remain. It should be noted that in consideration of the variations in thickness of the film, which are caused by the irregularity of the surface of the nickel silicide film and variations in the processes, the thickness of the nickel film should preferably be 0.5 or less with respect to that of the silicon layer being set to 1 in terms of ratio.

In the silicon layer 13 between the silicon germanium layer 12 and the nickel silicide layer 19, Ge from the silicon germanium 12 is diffused. When the Ge concentration of the silicon layer 13 in contact with the nickel silicide film is controlled to 10% or less, it is possible to prevent the degrading of the interfacial morphology of the silicide film, which is caused by the reaction between silicide and Ge.

As described above, according to the manufacturing method of this embodiment, it is possible to make a portion of the silicon layer remain between the silicide film and silicon germanium layer, and accordingly the degrading of the interfacial morphology of the silicide film, which is caused by the reaction between silicide and Ge, can be prevented. In this manner, the deterioration of the transistor characteristics in the MOS transistor can be prevented, and therefore the decreased in the yield of the semiconductor device can be suppressed.

Again, in a strict sense, Ge is dispersed in the silicon layer present between the silicide film and silicon germanium layer; however it is possible to prevent the degrading of the interfacial morphology of the silicide film by controlling the Ge concentration of the silicon layer 13 in contact with the silicide film to 10% or less.

### Second Embodiment

Next, a semiconductor device according to the second embodiment of the present invention will now be described. Similar structural parts to those of the first embodiment will be designated by the same reference numerals, respectively.

FIG. 10 is a cross sectional diagram showing the structure of the semiconductor device containing the MOSFET according to the second embodiment. As shown, a source region 15 and a drain region 16 are formed to be apart from each other in a surface region of a distorted silicon layer 13 formed on a silicon germanium layer 12. As the silicon germanium layer 12, a type that has a germanium concentration of 10 to 30% is used. A gate insulating film 17 is formed on that portion of the silicon germanium layer 12 which is located between the source region 15 and drain region 16, and a gate electrode 18 is formed on the gate insulating film 17. Further, a sidewall insulating film 20 is formed on a side surface of the gate electrode 18.

A silicon film 22 is formed on the source region 15 and drain region 16. On the silicon film 22, a silicide film 23 such as a nickel silicide (NiSi) film, cobalt silicide (CoSi₂) film, erbium silicide (ErSi₂) film, platinum silicide (PtSi) film or iridium silicide (IrSi) film is formed. The following description will be made in connection with the case where the nickel silicide film 23 is formed as an example. Here, the nickel silicide film 23 is formed on the surface of the silicon film 22 even over to the inside thereof, but does not reach the silicon germanium 12. At least the silicon film 22 or silicon layer 13 is present between the nickel silicide film 23 and silicon germanium 12. In a strict sense, there are some cases where germanium (Ge) is contained in the silicon film 22 or silicon layer 13 present between the nickel silicide film 23 and silicon germanium layer 12. In these cases, the concentration of Ge present in the boundary between the nickel silicide film 23 and the silicon film 22 or silicon layer 13 is controlled to 10% or less. In this manner, it is possible to prevent the degrading of the interfacial morphology of the nickel silicide film 23, which is caused by the reaction between silicide and Ge.

In the second embodiment, the silicon film 22 is formed on the silicon layer 13 that constitutes the source region 15 and drain region 16. With this structure, it is possible to adjust the distance from the surface of the silicon film 22 to the silicon germanium layer 12 regardless of the thickness of the distorted silicon layer 13. Therefore, the nickel film of a predetermined thickness can be deposited on the silicon film 22, and thus the nickel silicide film 19 having a predetermined thickness can be formed. The other advantages obtained in this embodiment are similar to those of the first embodiment.

As described above, according to the second embodiment, at least a silicon film or a silicon layer (or a silicon layer or film whose Ge concentration is 10% or less) is formed between the silicide layer and silicon germanium layer. With this structure, it is possible to prevent the deterioration of the interfacial morphology of the silicide film created by the reaction between silicide and Ge. In this manner, it becomes possible to prevent the dispersion of the resistance of the source region and drain region. Further, it is possible to prevent the increase in the junction leak current as well as the widening of the dispersion. Furthermore, the widening of the dispersion of the contact resistance of the contact portion formed on the source region and drain region, which is the three-element compound, can be presented. As a result, it is possible to suppress the lowering of the yield of the semiconductor device containing the MOSFET.

The method of manufacturing a semiconductor device containing a MOSFET according to the second embodiment shown in FIG. 10 will now be described.

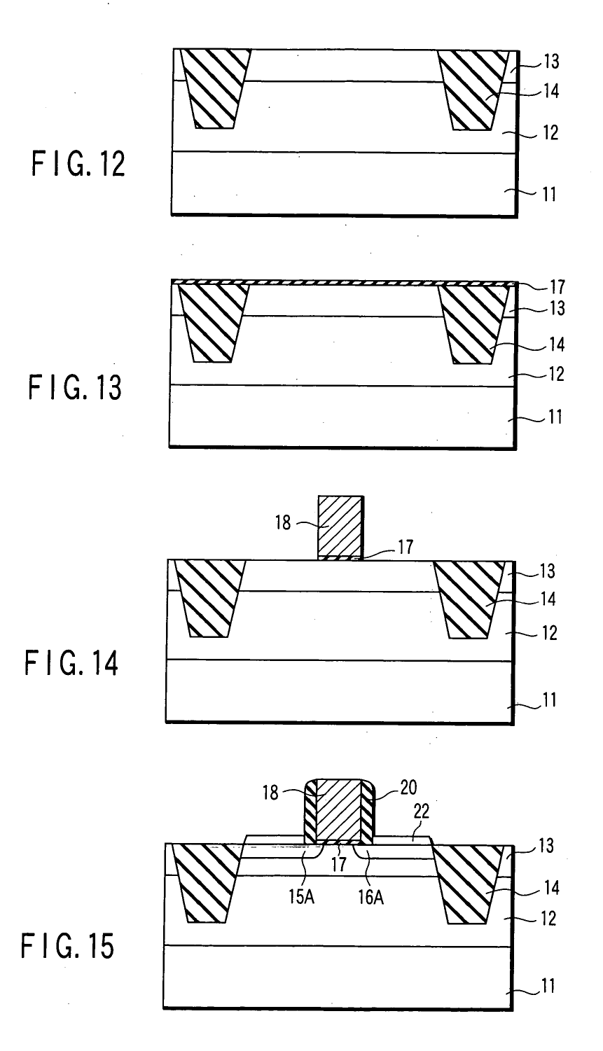

FIGS. 11 to 17 are cross sectional views each showing a respective step in the method of manufacturing the semiconductor device. First, as shown in FIG. 11, the silicon germanium layer 12 is formed on the silicon semiconductor substrate 11 and then the distorted silicon layer 13 is formed on the silicon germanium layer 12, both by a CVD method. Subsequently, as shown in FIG. 12, an element isolation insulating film (STI (shallow trench isolation)) 14 is formed in the silicon layer 13 and silicon germanium layer 12.

Next, as shown in FIGS. 13 and 14, a silicon oxide film 17 is formed on the silicon layer 13, and further a polysilicon film 18 is formed on the silicon oxide film 17. Then, the silicon oxide film 17 and polysilicon film 18 are etched by an RIE method, thereby forming a gate insulating film 17 and a gate electrode 18. After that, as shown in FIG. 15, extension regions 15A and 16A are formed in the surface regions of the silicon layer 13 on both sides of the gate electrode 18. After that, a sidewall insulating film 20 is formed on a side surface of the gate electrode 18.

Subsequently, a silicon film 22 is deposited selectively on portions of the silicon layer 13 that are located on both sides of the sidewall insulating film 20 by a CVD method. Further, an impurity is introduced to the surface regions of the silicon film 22 and silicon layer 13 on both sides of the sidewall insulating film 20 by an ion implantation method, thereby forming the source regions 15 and drain region 16.

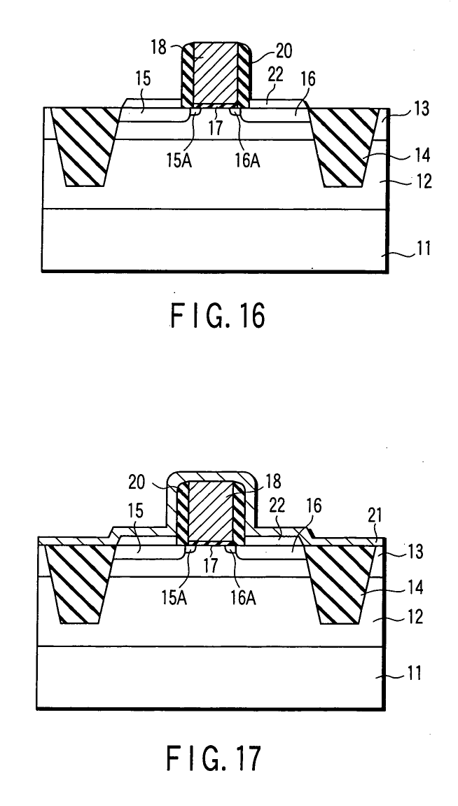

Next, a high-melting point metal film 21 such as of nickel (Ni), cobalt (Co), erbium (Er), platinum (Pt) or iridium (Ir) is deposited on the structure shown in FIG. 16, including the source region 15, drain region 16, gate electrode 18 and sidewall insulating film 20. In this embodiment, the descriptions will be made in connection with the case where a nickel film 21 is deposited as an example. Subsequently, a heat treatment is carried out to make the silicon film 22 and silicon layer 13 that constitute the source region 15 and drain region 16 and the polysilicon film that constitutes the gate electrode 18 react with the nickel film 21. Thus, the nickel film 21 is transformed into a silicide. After that, the unreacted portion of the nickel film 21 is removed, and a silicide film 23 is formed on the silicon film 22 formed on the source region 15 and drain region 16 and on the gate electrode 18 as shown in FIG. 10.

It should be noted here that the thickness of the nickel film 21 deposited on the silicon film 22 is set to 54% or less of the total thickness of the silicon film 22 and silicon layer 13 in order to avoid the nickel silicide film 23 formed by the reaction between silicon and nickel from contacting with the silicon germanium layer 12 located underneath the silicon layer 13. The reason for setting the total thickness of the silicon layer 13 and silicon film 22 to 54% or less is similar to that of the first embodiment.

In the case where a silicon germanium layer having a Ge concentration of 20% is used, the critical thickness with which dislocations do not occur through the distorted silicon layer formed above to be in contact with the silicon germanium layer is about 12 nm. Therefore, when a nickel layer is deposited to have a thickness of about 4 nm to 17 nm by a sputtering method, and a heat treatment is carried out to form a silicide film having a resistance of about 5 to 20Ω/□, the bottom surface of the silicide film is brought into contact with the silicon germanium layer. In order to avoid this, such a thickness of the nickel film that is necessary for obtaining a silicide film of a target resistance value should be calculated out, and further such a thickness of the silicon layer that is necessary for the formed silicide film not to be in contact with the silicon germanium layer should be calculated out. Then, the silicon film 22 that has an appropriate thickness obtained from the calculations is formed on the silicon layer 13. In this manner, it is possible to avoid the nickel silicide film 23 formed by the reaction between silicon and nickel from contacting with the silicon germanium layer 12 located underneath the silicon layer 13.

It should be noted that Ge from the silicon germanium 12 is diffused in the silicon layer 13; however when the Ge concentration of the silicon layer 13 in contact with the nickel silicide film is controlled to 10% or less, it is possible to prevent the degrading of the interfacial morphology of the silicide film, which is caused by the reaction between silicide and Ge.

As described above, according to the manufacturing method of this embodiment, it is possible to make a portion of the silicon layer remain between the silicide film and silicon germanium layer, and accordingly the degrading of the interfacial morphology of the silicide film, which is caused by the reaction between silicide and Ge, can be prevented. In this manner, the deterioration of the transistor characteristics in the MOS transistor can be prevented, and therefore the decreased in the yield of the semiconductor device can be suppressed.

Again, in a strict sense, Ge is dispersed in the silicon layer present between the silicide film and silicon germanium layer; however it is possible to prevent the degrading of the interfacial morphology of the silicide film by controlling the Ge concentration of the silicon layer in contact with the silicide film to 10% or less.

Further, with the silicon film formed on the silicon layer that constitutes the source region and drain region, it is possible to set the thickness of silicon on the silicon germanium layer. Therefore, the target silicide film can be formed without having the silicide film being contact with the silicon germanium layer.

According to this embodiment, it is possible to provide a semiconductor device including a MOSFET formed on a distorted silicon layer made on a silicon germanium layer, in which the deterioration of the transistor characteristics can be prevented and the decrease in the yield can be suppressed.

It should be noted that the present invention can take the following embodiment.

That is, a method of manufacturing a semiconductor device comprising: forming a silicon germanium layer on a semiconductor substrate; forming a gate insulating film on the silicon layer; forming a gate electrode on the gate insulating film; forming a source region and a drain region in those surface regions of the silicon which are located no both side of the gate electrode; and forming a silicide film on the source region and the drain region without making contact with the silicon germanium layer.

Further, the embodiments described above can be carried out not only separately but also in appropriate combination. Each of the embodiments contains various aspects of the invention and therefore various aspects of the invention can be extracted by appropriately combining structural elements of these embodiments together.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device comprising:
a silicon germanium layer formed on a semiconductor substrate;
a silicon layer formed on the silicon germanium layer; and
a silicide layer formed in a surface region of the silicon layer,
wherein a germanium concentration of the silicon layer that is in contact with the silicide film is 10% or less.

2. The semiconductor device according to claim 1, wherein the silicon layer contains germanium.

3. The semiconductor device according to claim 1, wherein a germanium concentration of the silicon germanium layer is 10% or more.

4. The semiconductor device according to claim 1, wherein the silicide film includes one of a nickel silicide film, a cobalt silicide film, an erbium silicide film, a platinum silicide film and an iridium silicide film.

5. A semiconductor device comprising:
a silicon germanium layer formed on a semiconductor substrate;
a silicon layer formed on the silicon germanium layer;
a first source region and a first drain region formed to be apart from each other in a surface region of the silicon layer;
a gate insulating film formed on the silicon layer and between the first source region and the first drain region;
a gate electrode formed on the gate insulating film;
a second source region and a second drain region formed on the first source region and the first drain region respectively, the second source region and the second drain region being each formed of a silicon film; and
silicide films formed on the second source region and the second drain region.

6. The semiconductor device according to claim 5, wherein at least one of the silicon layer and the silicon film is located between each of a lower surface of the silicide films and the silicon germanium layer.

7. The semiconductor device according to claim 5, wherein the silicon layer contains 10% or less of germanium.

8. The semiconductor device according to claim 7, wherein a germanium concentration of the silicon layer that is in contact with the silicide films is 10% or less.

9. The semiconductor device according to claim 5, wherein a germanium concentration of the silicon germanium layer is 10% or more.

10. The semiconductor device according to claim 5, wherein the silicide films include one of a nickel silicide film, a cobalt silicide film, an erbium silicide film, a platinum silicide film and an iridium silicide film.

11. The semiconductor device according to claim 5, wherein the silicon film is formed by a CVD method.
